(19) United States
(12) Patent Application Publication
(10) Pub. No.: US 2009/0090975 A1
(43) Pub. Date: Apr. 9, 2009

(54) INTEGRATED CIRCUIT SYSTEM EMPLOYING FLUORINE DOPING

(75) Inventors: Shiang Yang Ong, Singapore (SG); Shyue Seng Tan, Singapore (SG); Xiangdong Chen, Poughkeepsie, NY (US); Jae Gon Lee, Singapore (SG); Lee Wee Teo, Singapore (SG)

Correspondence Address: LAW OFFICES OF MIKIO ISHIMARU, 333 W. EL CAMINO REAL, SUITE 330, SUNNYVALE, CA, 94087, US

(73) Assignees: CHARTERED SEMICONDUCTOR MANUFACTURING LTD., Singapore (SG); INTERNATIONAL BUSINESS MACHINES CORPORATION, Armonk, NY (US)

(21) Appl. No.: 11/869,215

(22) Filed: Oct. 9, 2007

(51) Int. Cl. H01L 29/772

(52) U.S. Cl. 257/369; 257/E29.242

(57) ABSTRACT

An integrated circuit system that includes: providing a substrate including a first integrated circuit region electrically connected to a second integrated circuit region; implanting a dielectric growth material underneath a gate for each of an NFET device and a PFET device within the first integrated circuit region and the second integrated circuit region; and annealing the integrated circuit system.

### TECHNICAL FIELD

The present invention relates generally to integrated circuits, and more particularly to an integrated circuit system employing fluorine doping.

### BACKGROUND ART

Integrated circuits find application in many of today's consumer electronics, such as cell phones, video cameras, portable music players, printers, computers, etc. Integrated circuits may include a combination of active devices, passive devices and their interconnections.

A common active device within an integrated circuit is the metal-oxide-semiconductor field-effect transistor (MOSFET), which is commonly referred to as a field-effect transistor (FET). A MOSFET generally includes a semiconductor substrate, having a source, a drain, and a channel located between the source and drain. A gate stack including a conductive material (i.e.—a gate) and an oxide layer (i.e.—a gate oxide) are typically located above the channel. During operation, an inversion layer forms a conducting bridge or “channel” between the source and drain when an appropriate voltage is applied to the gate. Both p-channel and n-channel MOSFET technologies are available and can be combined on a single substrate in one technology, called complementary-metal-oxide-semiconductor or CMOS.

Integrated circuit devices that employ CMOS technology can be commonly found within memory devices, such as static random access memory (SRAM). Unfortunately, as the structural critical dimensions within these integrated circuit devices continues to decrease there is a concurrent increase in sub-threshold leakage current. Notably, gate related leakage current is rapidly becoming the major contributor to cell standby leakage current as the semiconductor industry continues its trend towards sub 65 nm technology. For example, in 65 nm node technology, gate related leakage current comprises about 25% of the leakage current of an SRAM cell in standby mode, but in the 45 nm technology node, gate related leakage current can comprise about 75% of the leakage current of an SRAM cell in standby mode. Consequently, techniques for reducing leakage current without reducing device functionality, such as by providing low standby power while the device is not being used, are becoming increasingly important to improve device performance.

To date, most proposed techniques for improving cell standby leakage current have proposed additional hardware configurations or additional processing steps (e.g.—additional masking steps for protecting logic circuitry), which either increase the area of an SRAM cell or add additional time consuming processing steps to the manufacturing method.

Thus, a need still remains for a reliable integrated circuit system and method of fabrication, wherein the integrated circuit system exhibits reduced standby leakage current. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including: providing a substrate including a first integrated circuit region electrically connected to a second integrated circuit region; implanting a dielectric growth material underneath a gate for each of an NFET device and a PFET device within the first integrated circuit region and the second integrated circuit region; and annealing the integrated circuit system.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit system in an initial stage of manufacture in accordance with an embodiment of the present invention;

FIG. 2 is the structure of FIG. 1 during a dielectric growth material implantation step;

FIG. 3 is the structure of FIG. 2 after further processing;

FIG. 4 is a cross-sectional view of an integrated circuit system in an initial stage of manufacture in accordance with another embodiment of the present invention;

FIG. 5 is the structure of FIG. 4 during an implant of a PFET device of a first integrated circuit region;

FIG. 6 is the structure of FIG. 5 during an implant of an NFET device of a first integrated circuit region;

FIG. 7 is the structure of FIG. 6 during an implant of a PFET device of a second integrated circuit region;

FIG. 8 is the structure of FIG. 7 during an implant of an NFET device of a second integrated circuit region;

FIG. 9 is an exemplary graphical representation of SRAM cell leakage for a logic/SRAM sample without a dielectric growth material implant versus a logic/SRAM sample with a 2×10¹⁵ (atoms/cm²) dielectric growth material implant versus a logic/SRAM sample with a 4×10¹⁵ (atoms/cm²) dielectric growth material implant;

FIG. 10 is a flow chart of an integrated circuit system for an integrated circuit system, in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGS. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over” and “under”, are defined with respect to the horizontal plane.

The term “processing” as used herein includes deposition of material or photoresist, patterning, exposure, development, etching, cleaning, and/or removal of the material or photoresist as required in forming a described structure.

The terms “example” or “exemplary” are used herein to mean serving as an instance or illustration. Any aspect or embodiment described herein as an “example” or as “exemplary” is not necessarily to be construed as preferred or advantageous over other aspects or designs.

The term “system” as used herein means and refers to the method and to the apparatus of the present invention in accordance with the context in which the term is used.

The term “on” is used herein to mean there is direct contact among elements.

The terms “first” and “second” as used herein are for purposes of differentiation between elements only and are not to be construed as limiting the scope of the present invention.

Generally, the present invention relates to the reduction of gate leakage current within an SRAM structure by subjecting a gate dielectric layer to a dielectric growth material implant. It has been discovered by the present inventors that by implanting the gate dielectric layer with a dielectric growth material that a 40% reduction in SRAM standby current can be achieved in sub 65 nanometer technology.

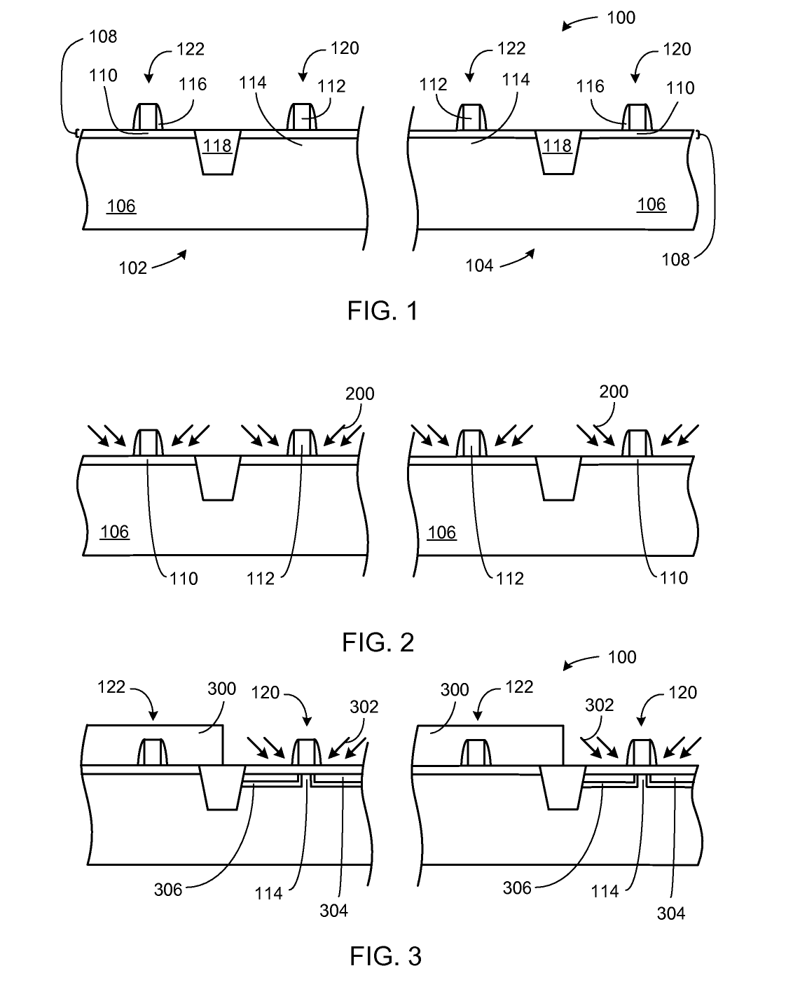

FIGS. 1-3, which follow, depict by way of example and not by limitation, an exemplary process flow for the formation of an integrated circuit system and they are not to be construed as limiting. It is to be understood that a plurality of conventional processes that are well known within the art and not repeated herein, may precede or follow FIGS. 1-3. Moreover, it is to be understood that many modifications, additions, and/or omissions may be made to the below described process without departing from the scope or spirit of the claimed subject matter. For example, the below described process may include more, fewer, or other steps.

Additionally, it is to be appreciated that the present disclosure need not be limited to the initial integrated circuit system depicted by FIG. 1. Accordingly, the present invention may include any number of multi-electrode devices in which the current flowing between two specified electrodes is controlled or modulated by the voltage applied at a control electrode. Exemplary illustrations may include an n-channel field effect transistor (NFET), a p-channel field effect transistor (PFET), a complementary metal-oxide-silicon (CMOS) configuration, a single-gate transistor, a multi-gate transistor, a fin-FET, or an annular gate transistor. Furthermore, it is to be understood that one or more of the integrated circuit system could be prepared at one time on a medium, which could be separated into individual or multiple integrated circuit assemblies at a later stage of fabrication.

Referring now to FIG. 1, therein is shown a cross-sectional view of an integrated circuit system 100 in an initial stage of manufacture in accordance with an embodiment of the present invention. By way of example, the integrated circuit system 100 may include devices selected from active components, passive components, processor components, memory components, logic components, digital components, analog components, power components, and so forth, in numerous configurations and arrangements as may be needed. It is to be understood that the integrated circuit system 100 can be formed from conventional deposition, patterning, photolithography, and etching steps.

The integrated circuit system 100 includes a first integrated circuit region 102 and a second integrated circuit region 104. Generally, the first integrated circuit region 102 may include a combination of active and passive devices that are in electrical communication with the second integrated circuit region, which may also include a combination of active and passive devices. In an aspect of the present embodiment, the first integrated circuit region 102 may include a logic circuit and the second integrated circuit region 104 may include a memory array, such as SRAM.

The integrated circuit system 100 further includes a substrate 106. By way of example, the substrate 106 may include any semiconducting material, such as, Si, SiC, SiGe, Si/SiGe, SiGeC, Ge, GaAs, InAs, InP, other III/V or II/VI compound semiconductors, as well as silicon-on-insulator configurations. Additionally, the substrate 106 may also include one or more crystal orientations (e.g.—(100) and (110) orientations), which may be strategically employed to enhance carrier mobility within NFET and PFET devices.

However, the examples provided for the substrate 106 are not to be construed as limiting and the composition of the substrate 106 may include any material that physically and electrically enables the formation of active and/or passive device structures.

A dielectric 108 is formed over the substrate 106. The dielectric 108 can be used to form a gate dielectric 110 for each of a gate 112. The dielectric 108 may include an oxygen containing material such as, but not limited to, silicon dioxide, silicon oxynitride, or a silicon oxide/nitride/oxide stack. However, it is to be understood that the type of material chosen for the dielectric 108 is not limited to the above examples and may include any material that permits growth (i.e.—an increase in thickness) of the dielectric 108 after implantation with a dielectric growth material.

The dielectric 108 may range in thickness from about ten (10) angstroms to about twenty-four (24) angstroms, for example. However, the thickness of the dielectric 108 is not to be limited to the preceding example, and may include any thickness that enhances the performance of the integrated circuit system 100.

Additionally, it is to be understood that the thickness of the dielectric 108 formed over the first integrated circuit region 102 and the second integrated circuit region 104 may be of equal or unequal thickness.

The gate 112 is formed above the gate dielectric 110 and a channel 114. By way of example, the gate 112 may include crystalline, polycrystalline, or amorphous silicon. In a preferred aspect of the invention, the gate 112 is polycrystalline silicon. However, it is to be understood that the gate 112 is not limited to the above examples and may include any conducting material, such as multiple layers of various conducting materials, for example.

A spacer 116, such as an offset spacer, can be formed adjacent each of the gate 112. By way of example, the spacer 116 may include a silicon nitride material, a silicon oxide material or a combination thereof, wherein the composition chosen depends upon the desired etch selectivity of the spacer 116. The thickness of the spacer 116 at its interface with the dielectric 108 can be adjusted to optimize the effects of a subsequent dielectric growth material implant and/or a subsequent extension and halo implant.

The substrate 106 may also include an isolation structure 118, such as a shallow trench isolation structure, which can electrically isolate and/or separate an NFET device 120 and a PFET device 122. For purposes of illustration, the isolation structure 118 can be made from a dielectric material such as silicon dioxide (“SiO₂”).

Referring now to FIG. 2, therein is shown the structure of FIG. 1 during a dielectric growth material implantation step. Arrows 200 depict the implantation of a dielectric growth material underneath each of the gate 112 by an angled implantation process that has been optimized to create a dielectric growth material implant range within the gate dielectric 110. In a preferred aspect of the present embodiment, the implantation process for the dielectric growth material can be optimized to localize the greatest concentration of the dielectric growth material at the interface of the substrate 106 and the gate dielectric 110. However, those skilled in the art will appreciate that some variation in the implant range of the dielectric growth material can occur.

It is to be understood that a multitude of implantation parameters, such as implant angle, implant dose and implant energy, can be adjusted to modulate the projected range of the dielectric growth material within the gate dielectric 110. For example, the implant angle may range from about zero (0) degrees to about forty-five (45) degrees, the implant dose may range from about 1×10¹³ to about 1×10¹⁶ (atoms/cm²) for the dielectric growth material, and the implant energy may range from about one (1) keV to about twenty (20) keV for the dielectric growth material. However, it is to be understood that these parameters are not limiting and those skilled in the art will appreciate that additional parameters may also be employed/manipulated to effectuate the purpose of implanting the dielectric growth material within the gate dielectric 110. Moreover, those skilled in the art will appreciate that the implantation parameters can vary with the thickness of the gate dielectric 110 and the dielectric growth material employed, for example.

In an aspect of the present embodiment, the dielectric growth material preferably includes fluorine. Not wishing to be limited to any particular theory, the present inventors believe that by strategically implanting fluorine within the gate dielectric 110 and/or at the interface of the substrate 106 and the gate dielectric 110 that fluorine can cause displacement of the oxygen within the gate dielectric 110 to its interfaces with the substrate 106 and the gate 112, thereby permitting additional oxide to be grown during a subsequent anneal.

Typically, after exposing the gate dielectric 110 to the dielectric growth material, the gate dielectric 110 experiences an increase in thickness between about 0.1 angstroms to about 1 angstrom, which correlates to about a 1% to about a 10% increase in thickness of the gate dielectric 110. As an exemplary illustration, the present inventors have discovered that a fluorine implant dose of about 1×10¹ to about 1×10¹⁶ (atoms/cm²) can thicken the gate dielectric 110 by about 0.2 to about 0.3 angstroms after annealing. An increase of about 0.2 to about 0.3 angstroms in the gate dielectric 110 thickness in sub 65 nanometer technology can help to reduce gate leakage current by up to about 60% and can help to reduce SRAM standby leakage current by about 40%. However, it is to be understood that the increase in thickness of the gate dielectric 110 is not to be limited to the preceding example, and may include any increase in thickness that enhances the performance of the integrated circuit system 100.

Notably, the present inventors have also discovered that in sub 65 nanometer node technology that a fluorine implant dosage above 1×10¹⁶ (atoms/cm²) begins to cause a degradation in the gate dielectric 110 integrity, thereby causing an increase in gate leakage current. Accordingly, in a preferred aspect of the present embodiment the fluorine implant dosage should contain less than 1×10¹⁶ (atoms/cm²) of the growth accelerating material.

Additionally, it is to be understood that the anneal, which can thicken the gate dielectric 110, can be performed at a later processing step, such as after a source/drain implant step. By way of example, the anneal may include any thermal process that causes the gate dielectric 110 to thicken after implantation with the dielectric growth material. As exemplary illustrations, the anneal may include a conventional activation anneal, a rapid thermal anneal, a spike anneal, a millisecond anneal, a flash anneal, and/or a laser anneal.

Referring now to FIG. 3, therein is shown the structure of FIG. 2 after further processing. A mask layer 300, such as a silicon nitride layer, can be formed over each of the PFET device 122. It is to be understood that the mask layer 300 need not be made of silicon nitride and may include any material that protects the PFET device 122 during subsequent processing of the NFET device 120. Arrows 302 represent the angled implantation of ions, which can form a source/drain extension 304 and a halo region 306 (e.g.—implanted with a p-type halo implant), adjacent the channel 114 within each of the NFET device 120. This ion implantation process is typically formed for threshold voltage adjustment purposes and/or for counteracting short channel effects within each of the NFET device 120.

It will be appreciated by those skilled in the art that after forming the source/drain extension 304 and the halo region 306, additional conventional steps, such as source/drain formation, silicide contact formation, interconnect formation, etc., can be performed as desired for each of the NFET device 120 and the PFET device 122.

Notably, after completion of the integrated circuit system 100 the standby leakage current of a sub 65 nanometer SRAM cell can be reduced by about 40% and the gate leakage current of a transistor device within the SRAM cell can be reduced by up to about 60%.

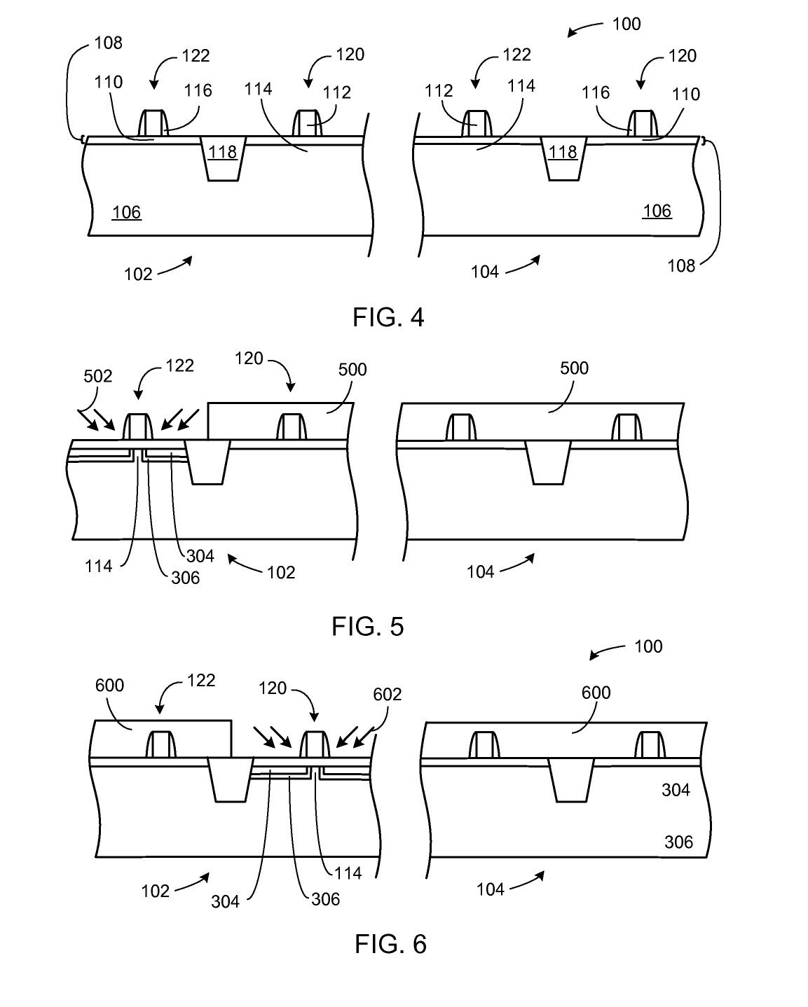

FIGS. 4-8, which follow, depict by way of example and not by limitation, an additional exemplary process flow for the formation of the integrated circuit system 100 and they are not to be construed as limiting. It is to be understood that a plurality of conventional processes that are well known within the art and not repeated herein, may precede or follow FIGS. 4-8. Moreover, it is to be understood that many modifications, additions, and/or omissions may be made to the below described process without departing from the scope or spirit of the claimed subject matter. For example, the below described process may include more, fewer, or other steps.

Additionally, it is to be appreciated that the present disclosure need not be limited to the integrated circuit system 100 depicted by FIG. 4. Accordingly, the present invention may include any number of multi-electrode devices in which the current flowing between two specified electrodes is controlled or modulated by the voltage applied at a control electrode. Exemplary illustrations may include an n-channel field effect transistor (NFET), a p-channel field effect transistor (PFET), a complementary metal-oxide-silicon (CMOS) configuration, a single-gate transistor, a multi-gate transistor, a fin-FET, or an annular gate transistor. Furthermore, it is to be understood that one or more of the integrated circuit system 100 could be prepared at one time on a medium, which could be separated into individual or multiple integrated circuit assemblies at a later stage of fabrication.

Referring now to FIG. 4, therein is shown a cross-sectional view of the integrated circuit system 100 in an initial stage of manufacture in accordance with another embodiment of the present invention. By way of example, the integrated circuit system 100 may include devices selected from active components, passive components, processor components, memory components, logic components, digital components, analog components, power components, and so forth, in numerous configurations and arrangements as may be needed. It is to be understood that the integrated circuit system 100 can be formed from conventional deposition, patterning, photolithography, and etching steps.

The integrated circuit system 100 includes the first integrated circuit region 102 and the second integrated circuit region 104. Generally, the first integrated circuit region 102 may include a combination of active and passive devices that are in electrical communication with the second integrated circuit region, which may also include a combination of active and passive devices. In an aspect of the present embodiment, the first integrated circuit region 102 may include a logic circuit and the second integrated circuit region 104 may include a memory array, such as SRAM.

The integrated circuit system 100 further includes the substrate 106. By way of example, the substrate 106 may include any semiconducting material, such as, Si, SiC, SiGe, Si/SiGe, SiGeC, Ge, GaAs, InAs, InP, other III/V or II/VI compound semiconductors, as well as silicon-on-insulator configurations. Additionally, the substrate 106 may also include one or more crystal orientations (e.g.—(100) and (110) orientations), which may be strategically employed to enhance carrier mobility within NFET and PFET devices.

However, the examples provided for the substrate 106 are not to be construed as limiting and the composition of the substrate 106 may include any material that physically and electrically enables the formation of active and/or passive device structures.

The dielectric 108 is formed over the substrate 106. The dielectric 108 can be used to form the gate dielectric 110 for each of the gate 112. The dielectric 108 may include an oxygen containing material such as, but not limited to, silicon dioxide, silicon oxynitride, or a silicon oxide/nitride/oxide stack. However, it is to be understood that the type of material chosen for the dielectric 108 is not limited to the above examples and may include any material that permits growth (i.e.—an increase in thickness) of the dielectric 108 after implantation with a dielectric growth material.

The dielectric 108 may range in thickness from about ten (10) angstroms to about twenty-four (24) angstroms, for example. However, the thickness of the dielectric 108 is not to be limited to the preceding example, and may include any thickness that enhances the performance of the integrated circuit system 100.

Additionally, it is to be understood that the thickness of the dielectric 108 formed over the first integrated circuit region 102 and the second integrated circuit region 104 may be of equal or unequal thickness.

The gate 112 is formed above the gate dielectric 110 and the channel 114. By way of example, the gate 112 may include crystalline, polycrystalline, or amorphous silicon. In a preferred aspect of the invention, the gate 112 is polycrystalline silicon. However, it is to be understood that the gate 112 is not limited to the above examples and may include any conducting material, such as multiple layers of various conducting materials, for example.

The spacer 116, such as an offset spacer, can be formed adjacent each of the gate 112. By way of example, the spacer 116 may include a silicon nitride material, a silicon oxide material or a combination thereof, wherein the composition chosen depends upon the desired etch selectivity of the spacer 116. The thickness of the spacer 116 at its interface with the dielectric 108 can be adjusted to optimize the effects of a subsequent dielectric growth material implant and/or a subsequent extension and halo implant.

The substrate 106 may also include the isolation structure 118, such as a shallow trench isolation structure, which can electrically isolate and/or separate the NFET device 120 and the PFET device 122. For purposes of illustration, the isolation structure 118 may be made from a dielectric material such as silicon dioxide (“SiO₂”).

Referring now to FIG. 5, therein is shown the structure of FIG. 4 during an implant of the PFET device 122 of the first integrated circuit region 102. A first mask layer 500, such as a silicon nitride layer, can be formed over the second integrated circuit region 104 and the NFET device 120 of the first integrated circuit region 102. It is to be understood that the first mask layer 500 need not be made of silicon nitride and may include any material that protects the second integrated circuit region 104 and the NFET device 120 of the first integrated circuit region 102. Arrows 502 represent the angled implantation of ions, which can form the source/drain extension 304 and the halo region 306 (e.g.—implanted with an n-type halo implant) adjacent the channel 114 of the PFET device 122 within the first integrated circuit region 102. This ion implantation process is typically formed for threshold voltage adjustment purposes and/or for counteracting short channel effects within the PFET device 122 of the first integrated circuit region 102.

Referring now to FIG. 6, therein is shown the structure of FIG. 5 during an implant of the NFET device 120 of the first integrated circuit region 102. The first mask layer 500, of FIG. 5, is removed (e.g.—by a wet or dry etch process) from over the integrated circuit system 100 and a second mask layer 600, such as a silicon nitride layer, can be formed over the second integrated circuit region 104 and the PFET device 122 of the first integrated circuit region 102. It is to be understood that the second mask layer 600 need not be made of silicon nitride and may include any material that protects the second integrated circuit region 104 and the PFET device 122 of the first integrated circuit region 102. Arrows 602 represent the angled implantation of ions, which can form the source/drain extension 304 and the halo region 306 (e.g.—implanted with a p-type halo implant) adjacent the channel 114 of the NFET device 120 within the first integrated circuit region 102. This ion implantation process is typically formed for threshold voltage adjustment purposes and/or for counteracting short channel effects within the NFET device 120 of the first integrated circuit region 102.

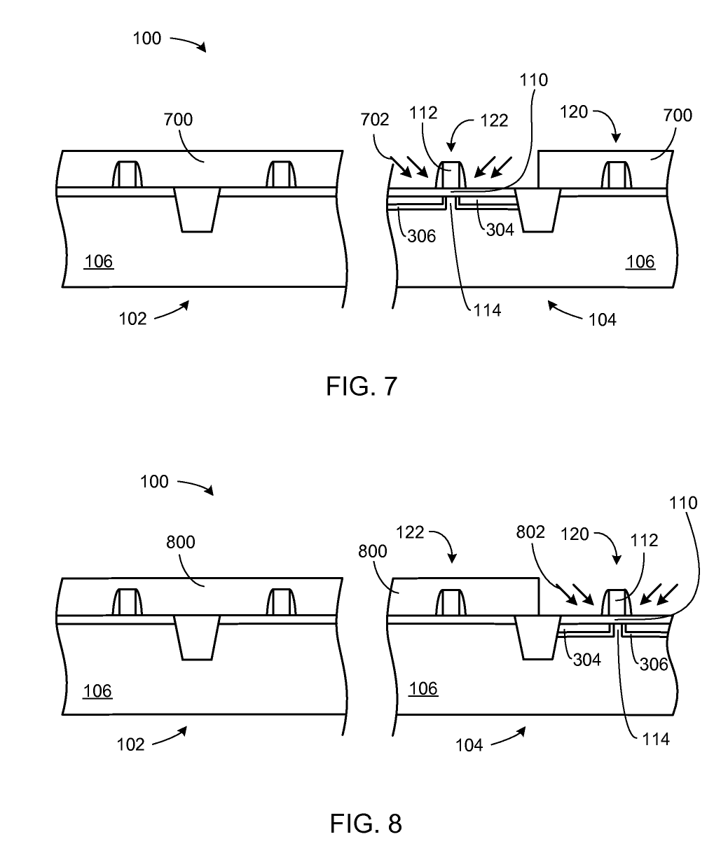

Referring now to FIG. 7, therein is shown the structure of FIG. 6 during an implant of the PFET device 122 of the second integrated circuit region 104. The second mask layer 600, of FIG. 6, is removed (e.g.—by a wet or dry etch process) from over the integrated circuit system 100 and a third mask layer 700, such as a silicon nitride layer, can be formed over the first integrated circuit region 102 and the NFET device 120 of the second integrated circuit region 104. It is to be understood that the third mask layer 700 need not be made of silicon nitride and may include any material that protects the first integrated circuit region 102 and the NFET device 120 of the second integrated circuit region 104. Arrows 702 represent the angled implantation of ions, which can form the source/drain extension 304 and the halo region 306 (e.g.—implanted with an n-type halo implant) adjacent the channel 114 of the PFET device 122 within the second integrated circuit region 104. This ion implantation process is typically formed for threshold voltage adjustment purposes and/or for counteracting short channel effects within the PFET device 122 of the second integrated circuit region 104.

The arrows 702 may also represent the angled implantation of a dielectric growth material underneath the gate 112 of the PFET device 122 within the second integrated circuit region 104. The dielectric growth material angled implantation can be optimized to create a dielectric growth material implant range within the gate dielectric 110 of the PFET device 122 within the second integrated circuit region 104. In a preferred aspect of the present embodiment, the implantation process for the dielectric growth material can be optimized to localize the greatest concentration of the dielectric growth material at the interface of the substrate 106 and the gate dielectric 110 of the PFET device 122 within the second integrated circuit region 104. However, those skilled in the art will appreciate that some variation in the implant range of the dielectric growth material can occur.

It is to be understood that a multitude of implantation parameters, such as implant angle, implant dose and implant energy, can be adjusted to modulate the projected range of the dielectric growth material within the gate dielectric 110. For example, the implant angle may range from about zero (0) degrees to about forty-five (45) degrees, the implant dose may range from about 1×10¹³ to about 1×10¹⁶ (atoms/cm²) for the dielectric growth material, and the implant energy may range from about one (1) keV to about twenty (20) keV for the dielectric growth material. However, it is to be understood these parameters are not limiting and those skilled in the art will appreciate that additional parameters may also be employed/manipulated to effectuate the purpose of implanting the dielectric growth material within the gate dielectric 110. Moreover, those skilled in the art will appreciate that the implantation parameters can vary with the thickness of the gate dielectric 110 and the dielectric growth material employed, for example.

In an aspect of the present embodiment, the dielectric growth material preferably includes fluorine. Not wishing to be limited to any particular theory, the present inventors believe that by strategically implanting fluorine within the gate dielectric 110 and/or at the interface of the substrate 106 and the gate dielectric 110 that fluorine can cause displacement of the oxygen within the gate dielectric 110 to its interfaces with the substrate 106 and the gate 112, thereby permitting additional oxide to be grown during a subsequent anneal.

Typically, after exposing the gate dielectric 110 to the dielectric growth material, the gate dielectric 110 experiences an increase in thickness between about 0.1 angstroms to about 1 angstrom, which correlates to about a 1% to about a 10% increase in thickness of the gate dielectric 110. As an exemplary illustration, the present inventors have discovered that a fluorine implant dose of about 1×10¹³ to about 1×10¹⁶ (atoms/cm²) can thicken the gate dielectric 110 by about 0.2 to about 0.3 angstroms after annealing. An increase of about 0.2 to about 0.3 angstroms in the gate dielectric 110 thickness in sub 65 nanometer technology helps to reduce gate leakage current by up to about 60% and can help to reduce SRAM standby leakage current by about 40%. However, it is to be understood that the increase in thickness of the gate dielectric 110 is not to be limited to the preceding example, and may include any increase in thickness that enhances the performance of the integrated circuit system 100.

Notably, the present inventors have also discovered that in sub 65 nanometer node technology that a fluorine implant dosage above 1×10¹⁶ (atoms/cm²) begins to cause a degradation in the gate dielectric 110 integrity, thereby causing an increase in gate leakage current. Accordingly, in a preferred aspect of the present embodiment the fluorine implant dosage should contain less than 1×10¹⁶ (atoms/cm²) of the growth accelerating material.

Additionally, it is to be understood that the anneal, which can thicken the gate dielectric 110, can be performed at a later processing step, such as after a source/drain implant step. By way of example, the anneal may include any thermal process that causes the gate dielectric 110 to thicken after implantation with the dielectric growth material. As exemplary illustrations, the anneal may include a conventional activation anneal, a rapid thermal anneal, a spike anneal, a millisecond anneal, a flash anneal, and/or a laser anneal.

Referring now to FIG. 8, therein is shown the structure of FIG. 7 during an implant of the NFET device 120 of the second integrated circuit region 104. The third mask layer 700, of FIG. 7, is removed (e.g.—by a wet or dry etch process) from over the integrated circuit system 100 and a fourth mask layer 800, such as a silicon nitride layer, can be formed over the first integrated circuit region 102 and the PFET device 122 of the second integrated circuit region 104. It is to be understood that the fourth mask layer 800 need not be made of silicon nitride and may include any material that protects the first integrated circuit region 102 and the PFET device 122 of the second integrated circuit region 104. Arrows 802 represent the angled implantation of ions, which can form the source/drain extension 304 and the halo region 306 (e.g.—implanted with an n-type halo implant) adjacent the channel 114 of the NFET device 120 within the second integrated circuit region 104. This ion implantation process is typically formed for threshold voltage adjustment purposes and/or for counteracting short channel effects within the NFET device 120 of the second integrated circuit region 104.

The arrows 802 may also represent the angled implantation of a dielectric growth material underneath the gate 112 of the NFET device 120 within the second integrated circuit region 104. The dielectric growth material angled implantation can be optimized to create a dielectric growth material implant range within the gate dielectric 110 of the NFET device 120 within the second integrated circuit region 104. In a preferred aspect of the present embodiment, the implantation process for the dielectric growth material can be optimized to localize the greatest concentration of the dielectric growth material at the interface of the substrate 106 and the gate dielectric 110 of the NFET device 120 within the second integrated circuit region 104. However, those skilled in the art will appreciate that some variation in the implant range of the dielectric growth material can occur.

It is to be understood that a multitude of implantation parameters, such as implant angle, implant dose and implant energy, can be adjusted to modulate the projected range of the dielectric growth material within the gate dielectric 110. For example, the implant angle may range from about zero (0) degrees to about forty-five (45) degrees, the implant dose may range from about 1×10¹³ to about 1×10¹⁶ (atoms/cm²) for the dielectric growth material, and the implant energy may range from about one (1) keV to about twenty (20) keV for the dielectric growth material. However, it is to be understood these parameters are not limiting and those skilled in the art will appreciate that additional parameters may also be employed/manipulated to effectuate the purpose of implanting the dielectric growth material within the gate dielectric 110. Moreover, those skilled in the art will appreciate that the implantation parameters can vary with the thickness of the gate dielectric 110 and the dielectric growth material employed, for example.

In an aspect of the present embodiment, the dielectric growth material preferably includes fluorine. Not wishing to be limited to any particular theory, the present inventors believe that by strategically implanting fluorine within the gate dielectric 110 and/or at the interface of the substrate 106 and the gate dielectric 110 that fluorine can cause displacement of the oxygen within the gate dielectric 110 to its interfaces with the substrate 106 and the gate 112, thereby permitting additional oxide to be grown during a subsequent anneal.

Typically, after exposing the gate dielectric 110 to the dielectric growth material, the gate dielectric 110 experiences an increase in thickness between about 0.1 angstroms to about 1 angstrom, which correlates to about a 1% to about a 10% increase in thickness of the gate dielectric 110. As an exemplary illustration, the present inventors have discovered that a fluorine implant dose of about 1×10¹³ to about 1×10¹⁶ (atoms/cm²) can thicken the gate dielectric 110 by about 0.2 to about 0.3 angstroms after annealing. An increase of about 0.2 to about 0.3 angstroms in the gate dielectric 110 thickness in sub 65 nanometer technology helps to reduce gate leakage current by up to about 60% and can help to reduce SRAM standby leakage current by about 40%. However, it is to be understood that the increase in thickness of the gate dielectric 110 is not to be limited to the preceding example, and may include any increase in thickness that enhances the performance of the integrated circuit system 100.

Notably, the present inventors have also discovered that in sub 65 nanometer node technology that a fluorine implant dosage above 1×10¹⁶ (atoms/cm²) begins to cause a degradation in the gate dielectric 110 integrity, thereby causing an increase in gate leakage current. Accordingly, in a preferred aspect of the present embodiment the fluorine implant dosage should contain less than 1×10¹⁶ (atoms/cm²) of the growth accelerating material.

Additionally, it is to be understood that the anneal, which can thicken the gate dielectric 110, can be performed at a later processing step, such as after a source/drain implant step. By way of example, the anneal may include any thermal process that causes the gate dielectric 110 to thicken after implantation with the dielectric growth material. As exemplary illustrations, the anneal may include a conventional activation anneal, a rapid thermal anneal, a spike anneal, a millisecond anneal, a flash anneal, and/or a laser anneal.

It will be appreciated by those skilled in the art that additional conventional steps, such as source/drain formation, silicide contact formation, interconnect formation, etc., can be performed as desired for each of the NFET device 120 and the PFET device 122 during or after the above process steps.

Notably, after completion of the integrated circuit system 100 the standby leakage current of a sub 65 nanometer SRAM cell can be reduced by about 40% and the gate leakage current of a transistor device within the SRAM cell can be reduced by up to about 60%.

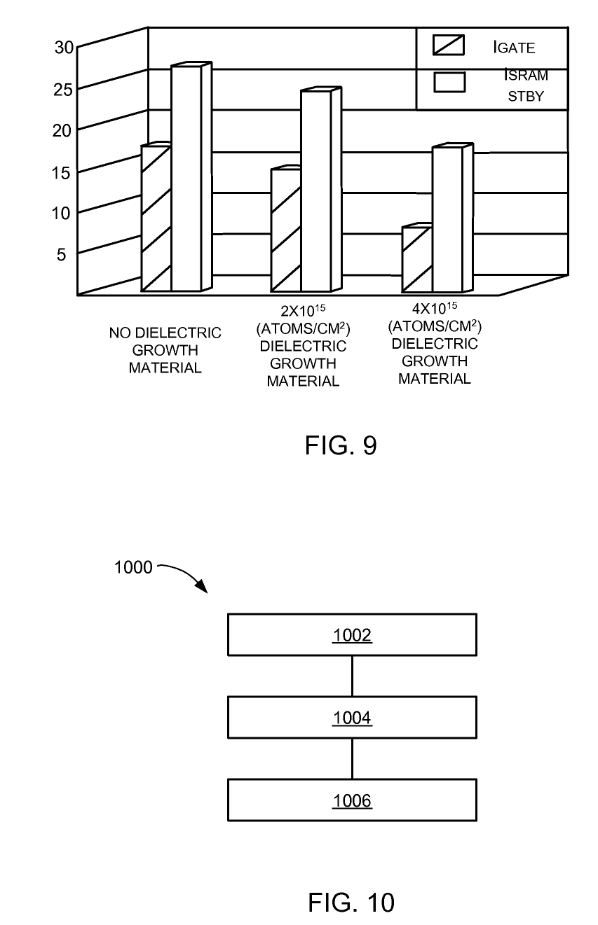

Referring now to FIG. 9, therein is shown an exemplary graphical representation of SRAM cell leakage for a logic/SRAM sample without a dielectric growth material implant versus a logic/SRAM sample with a 2×10¹⁵ (atoms/cm²) dielectric growth material implant versus a logic/SRAM sample with a 4×10¹⁵ (atoms/cm²) dielectric growth material implant. Notably, this graphical representation depicts approximately a 10% reduction in the SRAM cell standby leakage current and approximately a 16% reduction in gate leakage current for a logic/SRAM sample with a 2×10¹⁵ (atoms/cm²) dielectric growth material implant versus a logic/SRAM sample without a dielectric growth material implant. Remarkably, this graphical representation also depicts approximately a 40% reduction in the SRAM cell standby leakage current and approximately a 60% reduction in gate leakage current for a logic/SRAM sample with a 4×10¹⁵ (atoms/cm²) dielectric growth material implant versus a logic/SRAM sample without a dielectric growth material implant.

Referring now to FIG. 10, therein is shown a flow chart of an integrated circuit system 1000 for the integrated circuit system 100, in accordance with an embodiment of the present invention. The integrated circuit system 1000 includes providing a substrate including a first integrated circuit region electrically connected to a second integrated circuit region in a block 1002; implanting a dielectric growth material underneath a gate for each of an NFET device and a PFET device within the first integrated circuit region and the second integrated circuit region in a block 1004; and annealing the integrated circuit system in a block 1006.

It has been discovered that the present invention thus has numerous aspects. One such aspect is that the present invention enables a reduction in standby leakage current for a sub 65 nanometer SRAM cell. The present invention achieves this objective by strategically implanting selected gate dielectrics with a dielectric growth material that stimulates a thickening of the gate dielectric upon annealing.

Another aspect of the present invention is that it enables a reduction in gate leakage current of a transistor device by strategically implanting the gate dielectric of a transistor device with a dielectric growth material that stimulates a thickening of the gate dielectric upon annealing.

Another aspect of the present invention is that it can be implemented without requiring additional mask formations over the logic circuitry. By employing selective implantation of a dielectric growth material, the present invention achieves selective gate dielectric growth without adversely impacting logic circuitry performance.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for reducing device standby leakage currents. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
providing a substrate including a first integrated circuit region electrically connected to a second integrated circuit region;
implanting a dielectric growth material underneath a gate for each of an NFET device and a PFET device within the first integrated circuit region and the second integrated circuit region; and
annealing the integrated circuit system.

2. The system as claimed in claim 1 wherein:
providing the first integrated circuit region includes providing a logic circuit.

3. The system as claimed in claim 2 wherein:
providing the second integrated circuit region includes providing a memory array.

4. The system as claimed in claim 1 wherein:
implanting the dielectric growth material includes implanting fluorine.

5. The system as claimed in claim 1 wherein:
annealing the integrated circuit system includes thickening a gate dielectric for each of the NFET device and the PFET device.

6. An integrated circuit system comprising:
providing a substrate including a first integrated circuit region electrically connected to a second integrated circuit region;
implanting a dielectric growth material underneath a gate for each of an NFET device and a PFET device within the second integrated circuit region; and
annealing the integrated circuit system.

7. The system as claimed in claim 6 wherein:
providing the first integrated circuit region includes providing a logic circuit.

8. The system as claimed in claim 7 wherein:
providing the second integrated circuit region includes providing a memory array.

9. The system as claimed in claim 6 wherein:
implanting the dielectric growth material includes implanting fluorine.

10. The system as claimed in claim 6 wherein:
annealing the integrated circuit system includes thickening a gate dielectric for each of the NFET device and the PFET device within the second integrated circuit region.

11. An integrated circuit system comprising:
providing a substrate including a first integrated circuit region electrically connected to a second integrated circuit region;
forming a first mask layer to expose a PFET device within the first integrated circuit region for implanting a source/drain extension and a halo region;
removing the first mask layer and forming a second mask layer to expose an NFET device within the first integrated circuit region for implanting a source/drain extension and a halo region;
removing the second mask layer and forming a third mask layer to expose a PFET device within the second integrated circuit region for implanting a source/drain extension, a halo region, and a dielectric growth material;
removing the third mask layer and forming a fourth mask layer to expose an NFET device within the second integrated circuit region for implanting a source/drain extension, a halo region, and a dielectric growth material; and
annealing the integrated circuit system.

12. The system as claimed in claim 11 wherein:
implanting the dielectric growth material within the PFET device of the second integrated circuit region includes implanting the dielectric growth material underneath a gate of the PFET device of the second integrated circuit region.

13. The system as claimed in claim 11 wherein:
implanting the dielectric growth material within the NFET device of the second integrated circuit region includes implanting the dielectric growth material underneath a gate of the NFET device of the second integrated circuit region.

14. The system as claimed in claim 11 wherein:
implanting the dielectric growth material includes an implant dose ranging from about 1×10¹³ to about 1×10¹⁶ (atoms/cm²) for the dielectric growth material.

15. The system as claimed in claim 11 wherein:
implanting the dielectric growth material includes implanting fluorine.

16. The system as claimed in claim 11 wherein:
annealing the integrated circuit system includes thickening a gate dielectric for each of the NFET device and the PFET device within the second integrated circuit region.

17. The system as claimed in claim 11 wherein:
annealing the integrated circuit system includes thickening a gate dielectric by about 0.2 angstroms to about 0.3 angstroms for each of the NFET device and the PFET device within the second integrated circuit region.

18. The system as claimed in claim 11 wherein:
providing the first integrated circuit region includes providing a logic circuit.

19. The system as claimed in claim 18 wherein:
providing the second integrated circuit region includes providing a memory array.

20. The system as claimed in claim 11 wherein:
implanting the dielectric growth material includes localizing the greatest concentration of the dielectric growth material at an interface of the substrate and a gate dielectric of each of the PFET device and the NFET device within the second integrated circuit region.
